(19) United States
(12) Patent Application Publication
(10) Pub. No.: US 2023/0361749 A1
(43) Pub. Date: Nov. 9, 2023

(54) ACOUSTIC WAVE DEVICE AND METHOD FOR MANUFACTURING ACOUSTIC WAVE DEVICE

(71) Applicant: Murata Manufacturing Co., Ltd., Nagaokakyo-shi (JP)

(72) Inventor: Kazunori INOUE, Nagaokakyo-shi (JP)

(21) Appl. No.: 18/222,501

(22) Filed: Jul. 17, 2023

Related U.S. Application Data
(63) Continuation of application No. PCT/JP2022/004413, filed on Feb. 4, 2022.
(60) Provisional application No. 63/146,038, filed on Feb. 5, 2021.

(51) Int. Cl. H03H 9/02; H03H 9/13; H03H 3/02

(52) U.S. Cl. CPC H03H 9/02157; H03H 9/132; H03H 9/02031; H03H 3/02; H03H 2003/021

(57) ABSTRACT

An acoustic wave device includes a support substrate having a thickness in a first direction, a piezoelectric layer extending in the first direction of the support substrate, and an interdigital transducer electrode extending in the first direction of the piezoelectric layer and including first electrode fingers and second electrode fingers. The first electrode fingers extend in a second direction orthogonal to the first direction, and the second electrode fingers extend in the second direction and face corresponding ones of the first electrode fingers in a third direction orthogonal to the first and second directions. The support substrate has a recess on a side adjacent to the piezoelectric layer and at a position at least partially overlapping the interdigital transducer electrode in plan view in the first direction. A filling made of a material different from a material of the support substrate is included in a portion of the recess.

### CROSS REFERENCE TO RELATED APPLICATIONS

This application claims the benefit of priority to Provisional Application No. 63/146,038 filed on Feb. 5, 2021 and is a Continuation Application of PCT Application No. PCT/JP2022/004413 filed on Feb. 4, 2022. The entire contents of each application are hereby incorporated herein by reference.

### BACKGROUND OF THE INVENTION

### 1. Field of the Invention

The present disclosure relates to an acoustic wave device and a method for manufacturing an acoustic wave device.

### 2. Description of the Related Art

An acoustic wave device is disclosed in Japanese Unexamined Patent Application Publication No. 2012-257019.

### SUMMARY OF THE INVENTION

When a piezoelectric layer has a through hole communicating with a hollow in the technique disclosed in Japanese Unexamined Patent Application Publication No. 2012-257019, there is a possibility that cracks originating from the through hole may occur. Accordingly, it is necessary to reduce damage to the piezoelectric layer.

Preferred embodiments of the present invention reduce damage to the piezoelectric layer.

An acoustic wave device according to an aspect of a preferred embodiment of the present invention includes a support substrate having a thickness in a first direction, a piezoelectric layer extending in the first direction of the support substrate, and an interdigital transducer electrode extending in the first direction of the piezoelectric layer and including a plurality of first electrode fingers and a plurality of second electrode fingers. The plurality of first electrode fingers extend in a second direction orthogonal to the first direction, and the plurality of second electrode fingers extend in the second direction and face corresponding ones of the plurality of first electrode fingers in a third direction orthogonal to the first direction and the second direction. The support substrate includes a recess on a side thereof adjacent to the piezoelectric layer and at least partially overlapping the interdigital transducer electrode in plan view in the first direction. A filling made of a material different from a material of the support substrate is included in a portion of the recess.

A method for manufacturing an acoustic wave device according to an aspect of a preferred embodiment of the present invention includes forming a recess in a support substrate, filling the recess with a filler, placing a piezoelectric layer onto the support substrate after the filling step and combining the piezoelectric layer and the support substrate together, and applying heat treatment to the filler at a temperature higher than a processing temperature in the combining to shrink the filler and form a hollow in the recess.

Preferred embodiments of the present invention reduce damage to the piezoelectric layer.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a perspective view of an acoustic wave device according to a first preferred embodiment of the present invention.

FIG. 1B is a plan view of an electrode structure according to the first preferred embodiment of the present invention.

FIG. 2 is a cross-sectional view taken along line II-II of FIG. 1A.

FIG. 3A is a schematic cross-sectional view for explaining Lamb waves propagating in a piezoelectric layer of a comparative example.

FIG. 3B is a schematic cross-sectional view for explaining first-order thickness shear mode bulk waves propagating in a piezoelectric layer of the first preferred embodiment of the present invention.

FIG. 4 is a schematic cross-sectional view for explaining an amplitude direction of first-order thickness shear mode bulk waves propagating in the piezoelectric layer of the first preferred embodiment of the present invention.

FIG. 5 is an explanatory diagram illustrating an example of resonance characteristics of the acoustic wave device according to the first preferred embodiment of the present invention.

FIG. 6 is an explanatory diagram illustrating a relation between d/2p and a fractional bandwidth of the acoustic wave device of the first preferred embodiment of the present invention serving as a resonator, where p is a center-to-center distance or average center-to-center distance between adjacent electrodes and d is an average thickness of the piezoelectric layer.

FIG. 7 is a plan view illustrating an example of one electrode pair in an acoustic wave device according to the first preferred embodiment of the present invention.

FIG. 8 is a reference diagram illustrating an example of resonance characteristics of the acoustic wave device according to the first preferred embodiment of the present invention.

FIG. 9 is an explanatory diagram illustrating a relation between the fractional bandwidth of the acoustic wave device of the first preferred embodiment of the present invention included in each of many acoustic wave resonators, and the amount of phase rotation of impedance of spurious emission normalized at 180 degrees to represent the level of spurious emission.

FIG. 10 is an explanatory diagram illustrating a relation between d/2p, metallization ratio MR, and fractional bandwidth.

FIG. 11 is an explanatory diagram illustrating a map of fractional bandwidth with respect to Euler angles (0°, θ, ψ) of LiNbO₃ obtained when d/p is brought as close as possible to 0.

FIG. 12 is a partial cutaway perspective view for explaining an acoustic wave device according to a preferred embodiment of the present invention of the present disclosure.

FIG. 13 is a plan view illustrating Example 1 of the acoustic wave device according to the first preferred embodiment of the present invention.

FIG. 14 is a diagram illustrating an example of a cross-section taken along line XIV-XIV of FIG. 13.

FIG. 15 is a diagram illustrating another example of the cross-section taken along line XIV-XIV of FIG. 13.

FIG. 16 is a flowchart illustrating a method for manufacturing the acoustic wave device according to the first preferred embodiment of the present invention.

### DETAILED DESCRIPTION OF THE PREFERRED EMBODIMENTS

Preferred embodiments of the present disclosure will now be described in detail on the basis of the drawings. Note that the preferred embodiments described below do not limit the present disclosure. The preferred embodiments of the present disclosure are presented for illustrative purposes. In modifications and a second preferred embodiment where some components of different preferred embodiments can be replaced or combined, the description of matters common to the first preferred embodiment will be omitted and differences alone will be described. In particular, the same advantageous effects achieved by the same configurations will not be mentioned in the description of each preferred embodiment.

### First Preferred Embodiment

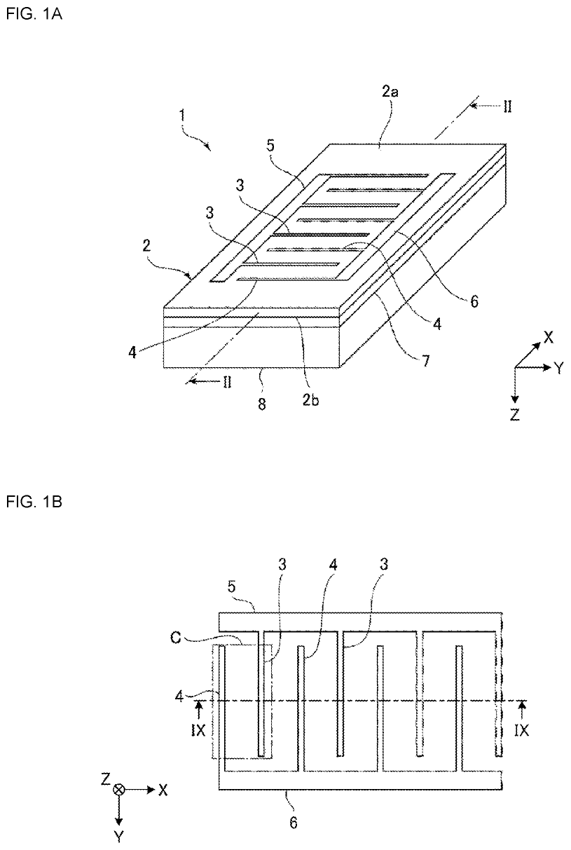

FIG. 1A is a perspective view of an acoustic wave device according to a first preferred embodiment. FIG. 1B is a plan view of an electrode structure according to the first preferred embodiment.

An acoustic wave device 1 according to the first preferred embodiment includes a piezoelectric layer 2 made of LiNbO₃. The piezoelectric layer 2 may be made of LiTaO₃. The cut-angles of LiNbO₃ and LiTaO₃ are Z-cut in the first preferred embodiment. The cut-angles of LiNbO₃ and LiTaO₃ may be rotated Y-cut or X-cut. It is preferable that the propagation orientation be Y-propagation and X-propagation ±30°.

The thickness of the piezoelectric layer 2 is not particularly limited. For effective excitation of first-order thickness shear mode, the thickness of the piezoelectric layer 2 is preferably greater than or equal to about 50 nm and less than or equal to about 1000 nm, for example.

The piezoelectric layer 2 includes a first principal surface 2a and a second principal surface 2b opposite each other in the Z direction. Electrode fingers 3 and 4 are arranged on the first principal surface 2a.

Here, the electrode finger 3 is an example of “first electrode finger”, and the electrode finger 4 is an example of “second electrode finger”. In FIGS. 1A and 1B, a plurality of electrode fingers 3 are a plurality of “first electrode fingers” connected to a first busbar 5, and a plurality of electrode fingers 4 are a plurality of “second electrode fingers” connected to a second busbar 6. The plurality of electrode fingers 3 and the plurality of electrode fingers 4 are interdigitated with each other. The electrode fingers 3, the electrode fingers 4, the first busbar 5, and the second busbar 6 thus define an interdigital transducer (IDT) electrode 30.

The electrode fingers 3 and 4 are rectangular in shape and have a length direction. In a direction orthogonal to the length direction, adjacent ones of the electrode fingers 3 and 4 face each other. Both the length direction of the electrode fingers 3 and 4 and the direction orthogonal to the length direction of the electrode fingers 3 and 4 are directions that cross the thickness direction of the piezoelectric layer 2. Therefore, adjacent ones of the electrode fingers 3 and 4 can also be considered facing each other in the direction crossing the thickness direction of the piezoelectric layer 2. Hereinafter, the thickness direction of the piezoelectric layer 2 may be described as a Z direction (or first direction), the length direction of the electrode fingers 3 and 4 may be described as a Y direction (or second direction), and the direction orthogonal to the electrode fingers 3 and 4 may be described as an X direction (or third direction).

The length direction of the electrode fingers 3 and 4 may be interchanged with the direction orthogonal to the length direction of the electrode fingers 3 and 4 illustrated in FIGS. 1A and 1B. That is, the electrode fingers 3 and 4 may extend in the direction in which the first busbar 5 and the second busbar 6 extend in FIGS. 1A and 1B. In this case, the first busbar 5 and the second busbar 6 extend in the direction in which the electrode fingers 3 and 4 extend in FIGS. 1A and 1B. A plurality of pairs of adjacent electrode fingers 3 and 4, the electrode finger 3 being connected to one potential and the electrode finger 4 being connected to the other potential, are arranged in the direction orthogonal to the length direction of the electrode fingers 3 and 4.

Here, the electrode fingers 3 and 4 adjacent to each other are not in direct contact, but are spaced from each other. The electrode fingers 3 and 4 adjacent to each other are not provided with other electrodes (including other electrode fingers 3 and 4) connected to hot and ground electrodes therebetween. The number of pairs of adjacent electrode fingers 3 and 4 does not necessarily need to be an integer, and there may be, for example, 1.5 pairs or 2.5 pairs.

A center-to-center distance, or pitch, between the electrode fingers 3 and 4 is preferably greater than or equal to about 1 μm and less than or equal to about 10 μm, for example. The center-to-center distance between the electrode fingers 3 and 4 is a distance from the center of the width dimension of the electrode finger 3 in the direction orthogonal to the length direction of the electrode finger 3 to the center of the width dimension of the electrode finger 4 in the direction orthogonal to the length direction of the electrode finger 4.

When the electrode fingers 3 and 4 include at least a plurality of electrode fingers 3 or a plurality of electrode fingers 4 (i.e., there are greater than or equal to 1.5 electrode pairs, each including the electrode finger 3 and the electrode finger 4), the center-to-center distance between the electrode fingers 3 and 4 is the average of the center-to-center distances between adjacent ones of the greater than or equal to 1.5 pairs of electrode fingers 3 and 4.

The width of the electrode fingers 3 and 4, or the dimension of the electrode fingers 3 and 4 in the direction in which the electrode fingers 3 and 4 face each other, is preferably greater than or equal to about 150 nm and less than or equal to about 1000 nm, for example. The center-to-center distance between the electrode fingers 3 and 4 is a distance from the center of the dimension (width dimension) of the electrode finger 3 in the direction orthogonal to the length direction of the electrode finger 3 to the center of the dimension (width dimension) of the electrode finger 4 in the direction orthogonal to the length direction of the electrode finger 4.

In the first preferred embodiment, where a Z-cut piezoelectric layer is used, the direction orthogonal to the length direction of the electrode fingers 3 and 4 is a direction orthogonal to the polarization direction of the piezoelectric layer 2. This is not applicable when a piezoelectric body with other cut-angles is used as the piezoelectric layer 2. Here, the term “orthogonal” may refer not only to being exactly orthogonal, but also to being substantially orthogonal (e.g., the angle between the direction orthogonal to the length direction of the electrode fingers 3 and 4 and the polarization direction is about 90°±10°).

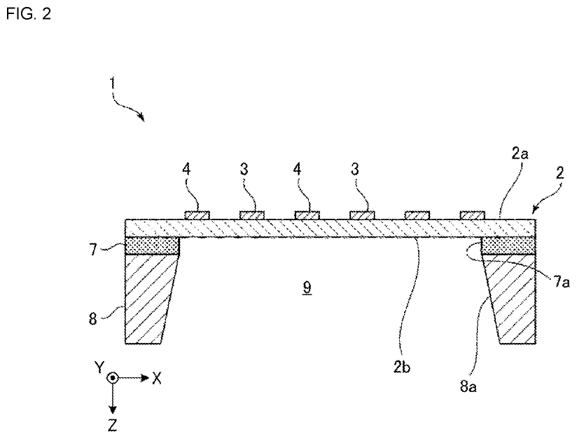

A support substrate 8 is disposed adjacent to the second principal surface 2b of the piezoelectric layer 2, with a dielectric film 7 interposed therebetween. The dielectric film 7 and the support substrate 8 have a frame-like shape. As illustrated in FIG. 2, the dielectric film 7 and the support substrate 8 are provided with cavities 7a and 8a, respectively, which define a hollow (air gap) 9.

The hollow 9 is provided to allow vibration of an excitation region C of the piezoelectric layer 2. Therefore, the support substrate 8 is disposed adjacent to the second principal surface 2b, with the dielectric film 7 interposed therebetween, so as not to overlap at least one pair of electrode fingers 3 and 4. The dielectric film 7 is optional. That is, the support substrate 8 may be disposed on the second principal surface 2b of the piezoelectric layer 2, either directly or indirectly.

The dielectric film 7 is made of silicon oxide. The dielectric film 7 can be made of an appropriate insulating material, such as silicon nitride or alumina, other than silicon oxide. The dielectric film 7 is an example of “intermediate layer”.

The support substrate 8 is made of Si. The plane orientation of the Si substrate on the surface thereof adjacent to the piezoelectric layer 2 may be (100), (110), or (111). It is preferable that the Si be a high-resistance Si with a resistivity of greater than or equal to about 4 kΩ, for example. The support substrate 8 can also be made of an appropriate insulating material or semiconductor material. Examples of the material used to form the support substrate 8 include piezoelectric materials, such as aluminum oxide, lithium tantalate, lithium niobate, and crystals; various ceramics, such as alumina, magnesia, sapphire, silicon nitride, aluminum nitride, silicon carbide, zirconia, cordierite, mullite, steatite, and forsterite; dielectrics, such as diamond and glass; and a semiconductor, such as gallium nitride.

The plurality of electrode fingers 3 and 4, the first busbar 5, and the second busbar 6 are made of an appropriate metal, such as Al, or an appropriate alloy, such as AlCu alloy. In the first preferred embodiment, the electrode fingers 3 and 4, the first busbar 5, and the second busbar 6 have a multilayer structure of a Ti film and an Al film on the Ti film. The Ti film may be replaced by a different adhesion layer.

To drive the acoustic wave device 1, an alternating-current voltage is applied between the plurality of electrode fingers 3 and the plurality of electrode fingers 4. More specifically, an alternating-current voltage is applied between the first busbar 5 and the second busbar 6. This can produce resonance characteristics using first-order thickness shear mode bulk waves excited in the piezoelectric layer 2.

In the acoustic wave device 1, d/p is less than or equal to about 0.5, for example, where d is the thickness of the piezoelectric layer 2 and p is the center-to-center distance between any adjacent electrode fingers 3 and 4 of the plurality of pairs of electrode fingers 3 and 4. This allows effective excitation of the first-order thickness shear mode bulk waves and can produce good resonance characteristics. It is more preferable that d/p be less than or equal to about 0.24, for example. This produces better resonance characteristics.

As in the first preferred embodiment, when the electrode fingers 3 and 4 include at least a plurality of electrode fingers 3 or a plurality of electrode fingers 4 (i.e., there are greater than or equal to 1.5 electrode pairs, each including the electrode finger 3 and the electrode finger 4), the center-to-center distance p between the adjacent electrode fingers 3 and 4 is the average center-to-center distance between all adjacent electrode fingers 3 and 4.

In the acoustic wave device 1 of the first preferred embodiment configured as described above, the Q factor does not decrease easily even if the number of pairs of the electrode fingers 3 and 4 is reduced for the purpose of size reduction. This is because the acoustic wave device 1 is a resonator that does not necessarily require reflectors on both sides, and thus does not suffer significant propagation loss. The acoustic wave device 1 does not require reflectors, because it uses first-order thickness shear mode bulk waves.

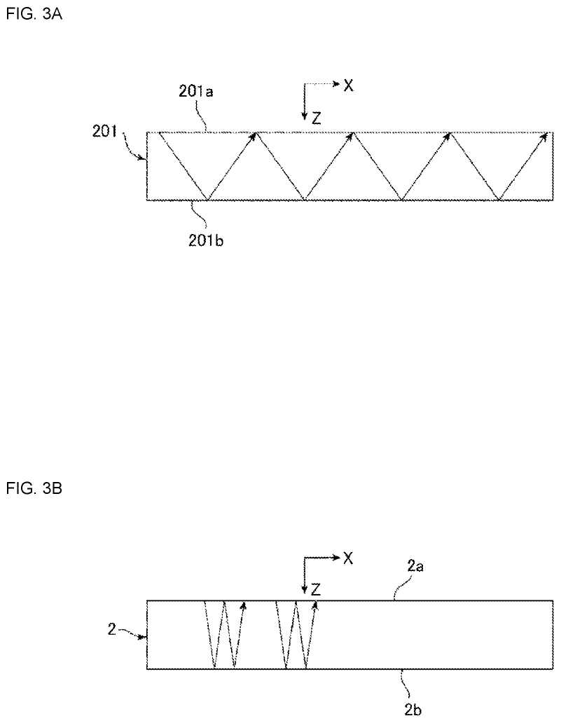

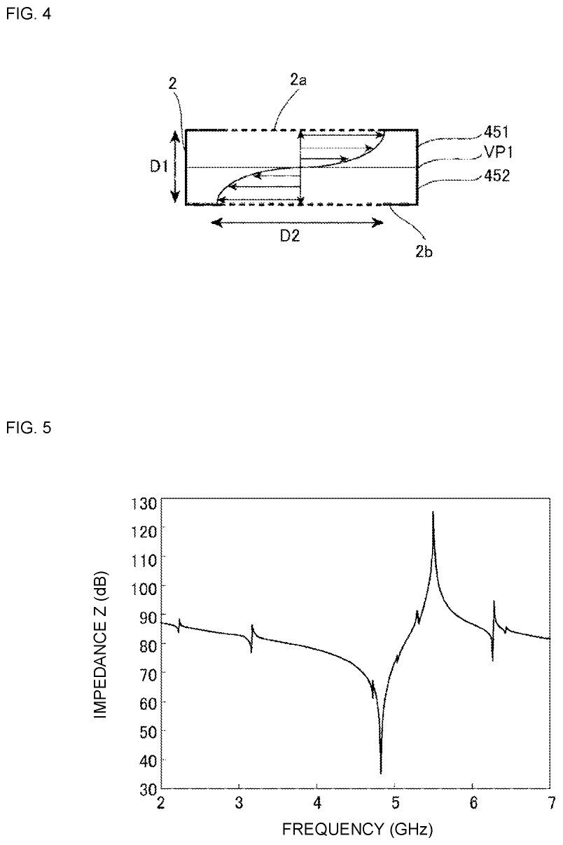

FIG. 3A is a schematic cross-sectional view for explaining Lamb waves propagating in a piezoelectric layer of a comparative example. FIG. 3B is a schematic cross-sectional view for explaining first-order thickness shear mode bulk waves propagating in the piezoelectric layer of the first preferred embodiment. FIG. 4 is a schematic cross-sectional view for explaining an amplitude direction of first-order thickness shear mode bulk waves propagating in the piezoelectric layer of the first preferred embodiment.

FIG. 3A illustrates Lamb waves propagating in a piezoelectric layer of an acoustic wave device, such as that described in Japanese Unexamined Patent Application Publication No. 2012-257019. As illustrated in FIG. 3A, the waves propagate in a piezoelectric layer 201 as indicated by arrows. The piezoelectric layer 201 includes a first principal surface 201a and a second principal surface 201b. A thickness direction, which connects the first principal surface 201a and the second principal surface 201b, is the Z direction. The X direction is a direction in which the electrode fingers 3 and 4 of the interdigital transducer electrode 30 are arranged. The Lamb waves propagate in the X direction, as illustrated in FIG. 3A. Although the entire piezoelectric layer 201 vibrates, the Lamb waves (plate waves) propagate in the X direction. Reflectors are thus provided on both sides to produce resonance characteristics. This causes wave propagation loss and results in a low Q factor when the number of pairs of the electrode fingers 3 and 4 is reduced for size reduction.

In the acoustic wave device of the first preferred embodiment, as illustrated in FIG. 3B, vibration displacement takes place in the thickness shear direction. Therefore, the waves propagate substantially in the direction connecting the first principal surface 2a and the second principal surface 2b of the piezoelectric layer 2, that is, substantially in the Z direction and resonate. In other words, the X direction component of the waves is much smaller than the Z direction component of the waves. Since the wave propagation in the Z direction produces resonance characteristics, the acoustic wave device requires no reflectors. This prevents propagation loss that occurs during propagation to reflectors. Therefore, the Q factor does not decrease easily even if the number of electrode pairs, each including the electrode fingers 3 and 4, is reduced for the purpose of size reduction.

As illustrated in FIG. 4, the amplitude direction of first-order thickness shear mode bulk waves in a first region 451 included in the excitation region C (see FIG. 1B) of the piezoelectric layer 2 is opposite that in a second region 452 included in the excitation region C. FIG. 4 schematically illustrates how bulk waves behave when a voltage that makes the potential of the electrode finger 4 higher than that of the electrode finger 3 is applied between the electrode fingers 3 and 4. In the excitation region C, the first region 451 is a region between a virtual plane VP1 and the first principal surface 2a, and the second region 452 is a region between the virtual plane VP1 and the second principal surface 2b. The virtual plane VP1 is orthogonal to the thickness direction of the piezoelectric layer 2 and divides the piezoelectric layer 2 into two.

The acoustic wave device 1 includes at least one electrode pair including the electrode fingers 3 and 4. Since the acoustic wave device 1 is not configured to propagate waves in the X direction, it is not necessarily required that there be more than one electrode pair including the electrode fingers 3 and 4. That is, the acoustic wave device 1 simply requires at least one electrode pair.

For example, the electrode finger 3 is an electrode connected to the hot potential, and the electrode finger 4 is an electrode connected to the ground potential. Alternatively, the electrode finger 3 and the electrode finger 4 may be connected to the ground potential and the hot potential, respectively. In the first preferred embodiment, the at least one electrode pair is a combination of electrodes, one connected to the hot potential and the other connected to the ground potential, as described above, and no floating electrode is provided.

FIG. 5 is an explanatory diagram illustrating an example of resonance characteristics of the acoustic wave device according to the first preferred embodiment. The design parameters of the acoustic wave device 1 having the resonance characteristics illustrated in FIG. 5 are as follows.

Piezoelectric layer 2: LiNbO₃ with Euler angles (0°, 0°, 90°)
Thickness of piezoelectric layer 2: 400 nm
Length of excitation region C (see FIG. 1B): 40 μm
Number of electrode pairs, each including electrode fingers 3 and 4: 21 pairs
Center-to-center distance (pitch) between electrode fingers 3 and 4: 3 μm
Width of electrode fingers 3 and 4: 500 nm
d/p: 0.133
Dielectric film 7: 1 μm-thick silicon oxide film
Support substrate 8: Si

The excitation region C (see FIG. 1B) is a region where the electrode fingers 3 and 4 overlap, as viewed in the X direction orthogonal to the length direction of the electrode fingers 3 and 4. The length of the excitation region C is a dimension of the excitation region C along the length direction of the electrode fingers 3 and 4. The excitation region C is an example of “overlap region”.

In the first preferred embodiment, all electrode pairs, each including the electrode fingers 3 and 4, have the same interelectrode distance. That is, the electrode fingers 3 and 4 are arranged with an equal pitch.

As is obvious from FIG. 5, good resonance characteristics with a fractional bandwidth of about 12.5% are obtained without reflectors, for example.

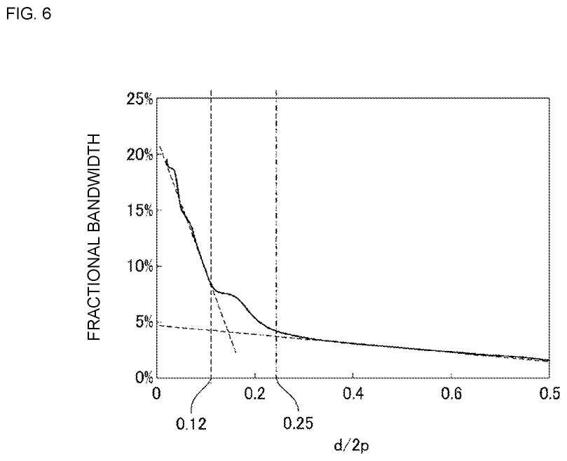

In the first preferred embodiment, d/p is less than or equal to about 0.5 and more preferably less than or equal to about 0.24, for example, where d is the thickness of the piezoelectric layer 2 and p is the center-to-center distance between the electrode fingers 3 and 4. This will now be described with reference to FIG. 6.

A plurality of acoustic wave devices are produced by varying d/2p of the acoustic wave device having the resonance characteristics illustrated in FIG. 5. FIG. 6 is an explanatory diagram illustrating a relation between d/2p and a fractional bandwidth of the acoustic wave device of the first preferred embodiment serving as a resonator, where p is the center-to-center distance between adjacent electrodes or the average center-to-center distance between adjacent electrodes, and d is the average thickness of the piezoelectric layer 2.

As illustrated in FIG. 6, if d/2p exceeds about 0.25 (or d/p>about 0.5), the fractional bandwidth falls below about 5% even when d/p is adjusted. On the other hand, if d/2p≤about 0.25 (or d/p≤about 0.5) is satisfied, the fractional bandwidth can be made greater than or equal to about 5% by varying d/p within the range, that is, a resonator having a high coupling coefficient can be obtained. If d/2p is less than or equal to about 0.12, that is, if d/p is less than or equal to about 0.24, the fractional bandwidth can be made as high as about 7% or more. Additionally, by adjusting d/p within this range, a resonator with a wider fractional bandwidth and a higher coupling coefficient can be produced. Thus, by making d/p less than or equal to about 0.5, a resonator with a higher coupling coefficient using first-order thickness shear mode bulk waves can be obtained.

It is simply required that there be at least one electrode pair. In the case of one electrode pair, p is the center-to-center distance between adjacent electrode fingers 3 and 4. In the case of greater than or equal to 1.5 electrode pairs, p may be the average center-to-center distance between adjacent electrode fingers 3 and 4.

If the piezoelectric layer 2 varies in thickness, the average thickness of the piezoelectric layer 2 may be used as the thickness d of the piezoelectric layer 2.

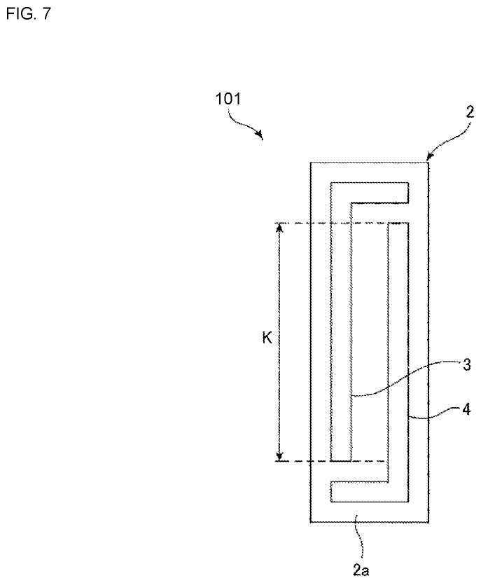

FIG. 7 is a plan view illustrating an example of one electrode pair in an acoustic wave device according to the first preferred embodiment. An acoustic wave device 101 includes one electrode pair including the electrode fingers 3 and 4 on the first principal surface 2a of the piezoelectric layer 2. Note that K in FIG. 7 indicates an overlap width. As described above, the acoustic wave device according to the present disclosure may include only one electrode pair. Even in this case, the first-order thickness shear mode bulk waves can be effectively excited if d/p is less than or equal to about 0.5, for example.

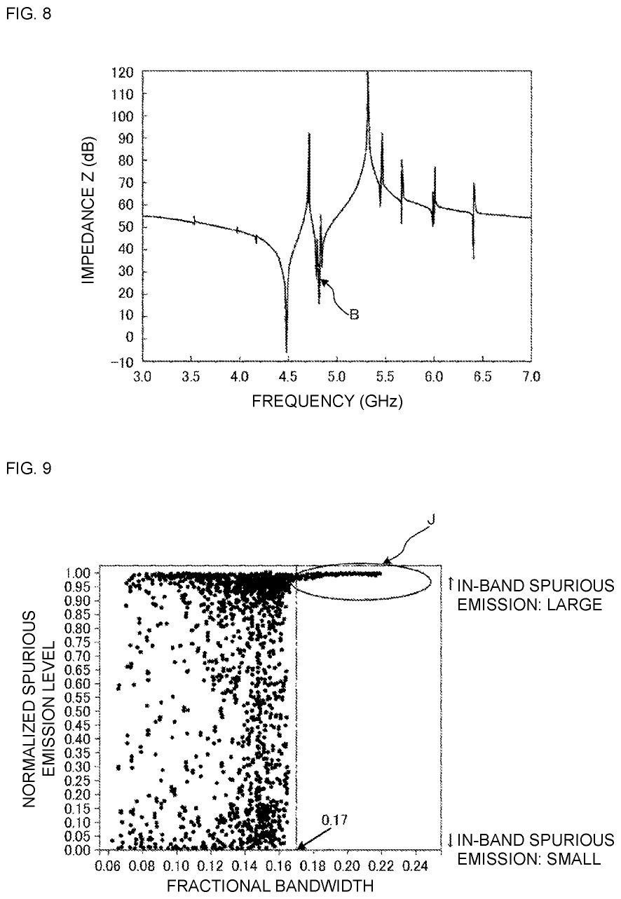

The excitation region C is a region where any adjacent electrode fingers 3 and 4 of the plurality electrode fingers 3 and 4 overlap as viewed in the direction in which the adjacent electrode fingers 3 and 4 face each other. It is preferable in the acoustic wave device 1 that MR≤about 1.75 (d/p)+0.075 be satisfied, for example, where MR is a metallization ratio MR of the adjacent electrode fingers 3 and 4 to the excitation region C. Spurious emission can be effectively reduced in this case. This will be described with reference to FIG. 8 and FIG. 9.

FIG. 8 is a reference diagram illustrating an example of resonance characteristics of the acoustic wave device according to the first preferred embodiment. Arrow B indicates a spurious emission appearing between the resonant frequency and the anti-resonant frequency. In this example, d/p is about 0.08, LiNbO₃ has Euler angles (0°, 0°, 90°), and the metallization ratio MR is about 0.35.

The metallization ratio MR will now be described with reference to FIG. 1B. To focus on one pair of electrode fingers 3 and 4 of the electrode structure in FIG. 1B, the description assumes that only the one pair of electrode fingers 3 and 4 is provided. In this case, a region enclosed by a dash-dot line is the excitation region C. When the electrode fingers 3 and 4 are viewed in the direction orthogonal to the length direction of the electrode fingers 3 and 4, or viewed in the direction in which the electrode fingers 3 and 4 face each other, the excitation region C includes a portion of the electrode finger 3 overlapping the electrode finger 4, a portion of the electrode finger 4 overlapping the electrode finger 3, and a portion between the electrode fingers 3 and 4 where the electrode fingers 3 and 4 face each other. The metallization ratio MR is the ratio of the area of the electrode fingers 3 and 4 in the excitation region C to the area of the excitation region C. That is, the metallization ratio MR is the ratio of the area of a metallized portion to the area of the excitation region C.

When a plurality of pairs of electrode fingers 3 and 4 are provided, MR may be the ratio of the area of metallized portions included in all excitation regions C to the sum of the areas of the excitation regions C.

FIG. 9 is an explanatory diagram illustrating a relation between the fractional bandwidth of the acoustic wave device of the first preferred embodiment included in each of many acoustic wave resonators, and the amount of phase rotation of impedance of spurious emission normalized at 180 degrees to represent the level of spurious emission. The fractional bandwidth is adjusted by varying the film thickness of the piezoelectric layer 2 or the dimensions of the electrode fingers 3 and 4. FIG. 9 illustrates a result of using a Z-cut LiNbO₃ layer as the piezoelectric layer 2. A similar tendency is observed when the piezoelectric layer 2 with other cut-angles is used.

In the region enclosed by oval J in FIG. 9, the level of spurious emission is as high as about 1.0, for example. As is clear from FIG. 9, when the fractional bandwidth exceeds about 0.17 or about 17%, for example, a large spurious emission with a spurious emission level of 1 or higher appears in the pass band even if parameters defining the fractional bandwidth are changed. That is, as in the resonance characteristics illustrated in FIG. 8, a large spurious emission indicated by arrow B appears in the band. Therefore, it is preferable that the fractional bandwidth be less than or equal to about 17%, for example. In this case, adjusting the film thickness of the piezoelectric layer 2 or the dimensions of the electrode fingers 3 and 4 can reduce spurious emission.

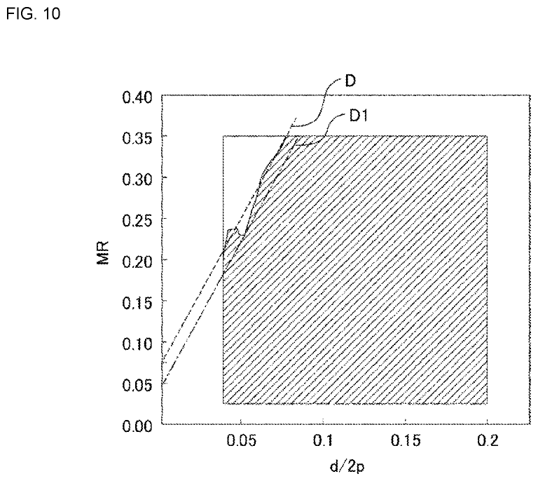

FIG. 10 is an explanatory diagram illustrating a relation between d/2p, metallization ratio MR, and fractional bandwidth. Various acoustic wave devices 1 of the first preferred embodiment are made by varying d/2p and MR to measure the fractional bandwidths. In FIG. 10, a hatched region to the right of broken line D is a region where the fractional bandwidth is less than or equal to about 17%, for example. The boundary between the hatched and non-hatched regions is represented by MR=about 3.5 (d/2p)+0.075 or MR=about 1.75 (d/p)+0.075, and preferably MR≤about 1.75 (d/p)+0.075, for example. In this case, it is easier to make the fractional bandwidth less than or equal to about 17%, for example. A more preferable region is one that is to the right of the boundary represented by MR=about 3.5 (d/2p)+0.05, indicated by dash-dot line D1 in FIG. 10, for example. That is, if MR≤about 1.75 (d/p)+0.05 is satisfied, the fractional bandwidth can be reliably made less than or equal to about 17%, for example.

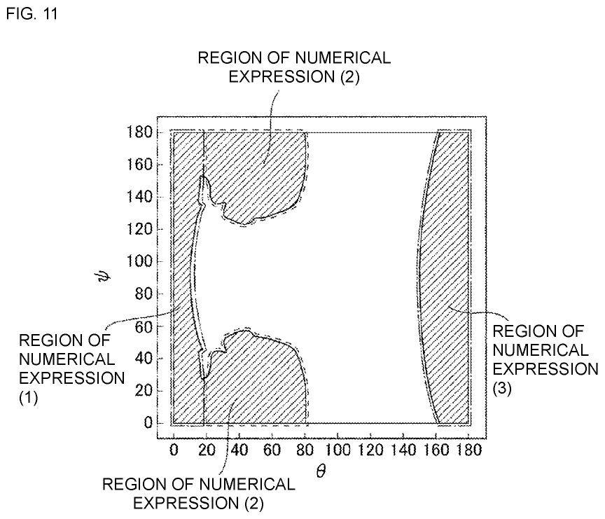

FIG. 11 is an explanatory diagram illustrating a map of fractional bandwidth with respect to Euler angles (0°, θ, ψ) of LiNbO₃ obtained when d/p is brought as close as possible to 0. Hatched regions in FIG. 11 are regions where a fractional bandwidth of at least greater than or equal to about 5% can be obtained. By approximating the ranges of these regions, ranges defined by numerical expression (1), numerical expression (2) and numerical expression (3) described below are obtained.

(0°±10°, 0° to 20°, any ψ) numerical expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) numerical expression (2)

(0°±10°, [180°−30° (1−(ψ−90)²/8100)^{1/2}] to 180°, any ψ) numerical expression (3)

The ranges of the Euler angles defined by numerical expression (1), numerical expression (2), or numerical expression (3) are preferable, because a sufficiently wide fractional bandwidth can be achieved.

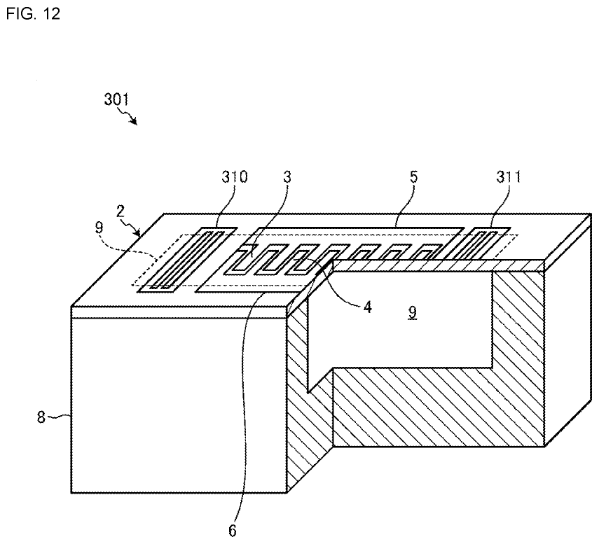

FIG. 12 is a partial cutaway perspective view for explaining an acoustic wave device according to a preferred embodiment of the present disclosure. In FIG. 12, the outer edge of the hollow 9 is indicated by a broken line. The acoustic wave device of the present disclosure may use plate waves. In this case, an acoustic wave device 301 includes reflectors 310 and 311, as illustrated in FIG. 12. The reflectors 310 and 311 are disposed on both sides of the electrode fingers 3 and 4 on the piezoelectric layer 2 in the propagation direction of acoustic waves. In the acoustic wave device 301, Lamb waves (or plate waves) are excited by applying an alternating-current electric field to the electrode fingers 3 and 4 above the hollow 9. With the reflectors 310 and 311 on both sides, the resonance characteristics based on Lamb waves (or plate waves) can be obtained.

As described above, the acoustic wave devices 1 and 101 use first-order thickness shear mode bulk waves. In the acoustic wave devices 1 and 101, the first and second electrode fingers 3 and 4 are adjacent electrodes and d/p is less than or equal to about 0.5, for example, where d is the thickness of the piezoelectric layer 2 and p is the center-to-center distance between the first and second electrode fingers 3 and 4. This can improve the Q factor even when the acoustic wave device is reduced in size.

In the acoustic wave devices 1 and 101, the piezoelectric layer 2 is made of lithium niobate or lithium tantalate. The first principal surface 2a or the second principal surface 2b of the piezoelectric layer 2 has thereon the first and second electrode fingers 3 and 4 facing each other in the direction crossing the thickness direction of the piezoelectric layer 2. The first and second electrode fingers 3 and 4 are preferably covered with a protective film.

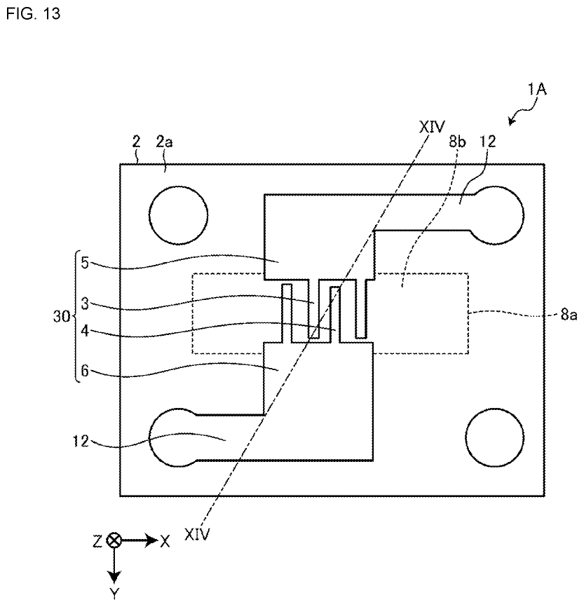

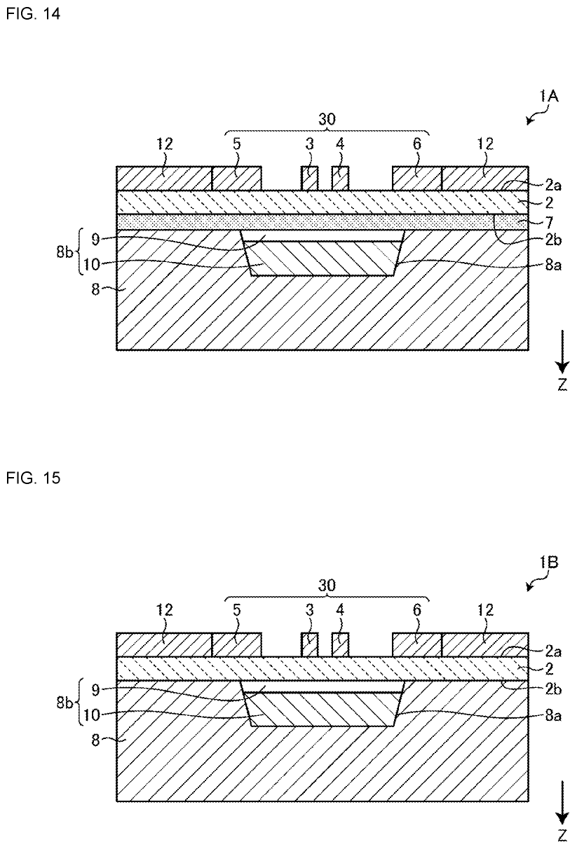

FIG. 13 is a plan view illustrating Example 1 of the acoustic wave device according to the first preferred embodiment. FIG. 14 is a diagram illustrating an example of a cross-section taken along line XIV-XIV of FIG. 13. The busbars 5 and 6 are connected to wires 12 on the first principal surface 2a of the piezoelectric layer 2 in the example illustrated in FIG. 13, but this is merely an example.

As illustrated in FIG. 13 and FIG. 14, in an acoustic wave device 1A according to the first preferred embodiment, the support substrate 8 has a recess 8b in the surface thereof adjacent to the piezoelectric layer 2 in the Z direction. The recess 8b at least partially overlaps the interdigital transducer electrode 30 in plan view in the Z direction. In the example illustrated in FIG. 14, the recess 8b is a space surrounded by the support substrate 8 and the dielectric film 7. The recess 8b includes the hollow 9 and a filling 10.

As illustrated in FIG. 13, in the acoustic wave device 1A according to Example 1, the piezoelectric layer 2 does not have a hole (through hole) penetrating the piezoelectric layer 2 at the position overlapping the recess 8b in plan view in the Z direction. The occurrence of cracks in the piezoelectric layer 2 originating from a through hole can thus be prevented.

The hollow 9 is a space formed after the filler in the recess 8b is shrunk by heat treatment, in the process of manufacturing the acoustic wave device 1A described below. In the example illustrated in FIG. 14, the hollow 9 is disposed between the dielectric film 7 and the filling 10 in the recess 8b. That is, the hollow 9 is a space surrounded by the filling 10, the cavity 8a in the support substrate 8, and the dielectric film 7. The hollow 9 can thus allow vibration of the piezoelectric layer 2.

The filling 10 is formed after the filler in the recess 8b is shrunk by heat treatment, in the process of manufacturing the acoustic wave device 1A described below. In the example illustrated in FIG. 14, the filling 10 is disposed in the recess 8b in such a way as to avoid contact with the dielectric film 7. In the first preferred embodiment, the filling 10 is a compound of silicon and metal, or a polyimide resin including copper, that is, a mixture of copper and polyimide resin. When the filling 10 is a compound of silicon and metal, the metal is one that forms a compound with silicon, such as gold or tin.

The maximum thickness of the filling 10 is preferably greater than the thickness of the hollow 9. The maximum thickness of the filling 10 is a maximum distance from the bottom surface of the recess 8b in the support substrate 8 to the surface of the filling 10 exposed to the hollow 9. Note that the bottom surface of the recess 8b in the support substrate 8 is the surface of the recess 8b in the support substrate 8 most distant from the second principal surface 2b of the piezoelectric layer 2 in the Z direction. The thickness of the hollow 9 is an average distance from the surface of the filling 10 exposed to the hollow 9 to the surface of the dielectric film 7 exposed to the hollow 9.

In the example illustrated in FIG. 14, the acoustic wave device 1A includes the dielectric film 7 between the piezoelectric layer 2 and the support substrate 8. The dielectric film 7 is disposed to overlap the recess 8b in plan view in the Z direction. The thickness of the dielectric film 7 is preferably smaller than the thickness of the piezoelectric layer 2. This can reduce degradation of frequency characteristics of the acoustic wave device 1A.

FIG. 15 is a diagram illustrating another example of the cross-section of the acoustic wave device according to the first preferred embodiment. The dielectric film 7 is optional and may be absent, as illustrated in FIG. 15. When the dielectric film 7 is absent, the thickness of the hollow 9 is an average distance from the surface of the filling 10 exposed to the hollow 9 to the second principal surface 2b of the piezoelectric layer 2.

As described above, the acoustic wave devices 1A and 1B according to the first preferred embodiment include the support substrate 8 having a thickness in the first direction, the piezoelectric layer 2 disposed in the first direction of the support substrate 8, and the interdigital transducer electrode 30 disposed in the first direction of the piezoelectric layer 2 and including the plurality of first electrode fingers 3 and the plurality of second electrode fingers 4. The plurality of first electrode fingers 3 extend in the second direction orthogonal to the first direction, and the plurality of second electrode fingers 4 extend in the second direction and face corresponding ones of the plurality of first electrode fingers 3 in the third direction orthogonal to the first direction and the second direction. The support substrate 8 has the recess 8b on the side thereof adjacent to the piezoelectric layer 2. The recess 8b is disposed at a position at least partially overlapping the interdigital transducer electrode 30 in plan view in the first direction. The filling 10 made of a material different from a material of the support substrate 8 is disposed in a portion of the recess 8b.

This configuration, which does not require a through hole, can prevent the occurrence of cracks in the piezoelectric layer 2 originating from a through hole. This can reduce damage to the piezoelectric layer 2.

In a preferred embodiment, the piezoelectric layer 2 does not have a through hole penetrating the piezoelectric layer 2 at a position overlapping the recess 8b in plan view in the first direction. This can reduce the occurrence of cracks in the piezoelectric layer 2 originating from a through hole, and thus can reduce damage to the piezoelectric layer 2.

In a preferred embodiment, a material of the filling 10 is a polyimide including copper. This allows the hollow 9 to be formed without a through hole, and thus can reduce damage to the piezoelectric layer 2.

In a preferred embodiment, a material of the filling 10 is a compound of silicon and metal. This allows the hollow 9 to be formed without a through hole, and thus can reduce damage to the piezoelectric layer 2.

In a preferred embodiment, the support substrate 8 and the piezoelectric layer 2 are provided with an intermediate layer (dielectric film 7) therebetween, and the intermediate layer (dielectric film 7) may overlap the recess 8b in plan view in the first direction. This can enhance adhesion between the piezoelectric layer 2 and the support substrate 8.

In a more preferred embodiment, the thickness of the intermediate layer (dielectric film 7) is smaller than the thickness of the piezoelectric layer 2. This can reduce degradation of frequency characteristics of the piezoelectric layer 2.

In a preferred embodiment, when the recess 8b includes the hollow 9 outside the filling 10, the maximum thickness of the filling 10 is greater than the thickness of the hollow 9. This can still reduce damage to the piezoelectric layer 2.

In a preferred embodiment, the thickness of the piezoelectric layer 2 is less than or equal to 2p, where p is a center-to-center distance between adjacent first and second electrode fingers 3 and 4 of the plurality of first and second electrode fingers 3 and 4. This can reduce the size of the acoustic wave device 1 and improve the Q factor.

In a more preferred embodiment, the piezoelectric layer 2 includes lithium niobate or lithium tantalate. This makes it possible to provide an acoustic wave device having good resonance characteristics.

In a more preferred embodiment, Euler angles (φ, θ, ψ) of lithium niobate or lithium tantalate forming the piezoelectric layer 2 are in the range defined by numerical expression (1), numerical expression (2), or numerical expression (3) described below. This can sufficiently widen the fractional bandwidth.

(0°±10°, 0° to 20°, any ψ) numerical expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) numerical expression (2)

(0°±10°, [180°−30° (1−(ψ−90)²/8100)^{1/2}] to 180°, any ψ) numerical expression (3)

In a preferred embodiment, the acoustic wave device 1 is configured to be capable of using thickness shear mode bulk waves. This improves the coupling coefficient and makes it possible to provide an acoustic wave device having good resonance characteristics.

In a more preferred embodiment, d/p≤about 0.5 is satisfied, where d is the thickness of the piezoelectric layer 2 and p is the center-to-center distance between adjacent first and second electrode fingers 3 and 4. This can reduce the size of the acoustic wave device 1 and improve the Q factor.

In a more preferred embodiment, d/p is less than or equal to about 0.24. This can reduce the size of the acoustic wave device 1 and improve the Q factor.

In a preferred embodiment, when a region where adjacent first and second electrode fingers 3 and 4 overlap in a direction in which the adjacent electrode fingers 3 and 4 face each other is the excitation region C, MR≤about 1.75 (d/p)+0.075 is satisfied, where MR is the metallization ratio of the plurality of first and second electrode fingers 3 and 4 to the excitation region C. This can reliably make the fractional bandwidth less than or equal to about 17%, for example.

In a preferred embodiment, the acoustic wave device 301 is configured to be capable of using plate waves. This makes it possible to provide an acoustic wave device having good resonance characteristics.

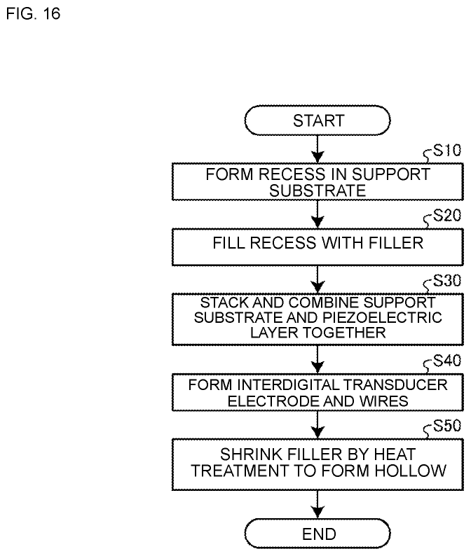

FIG. 16 is a flowchart illustrating a method for manufacturing the acoustic wave device according to the first preferred embodiment. Hereinafter, a method for manufacturing the acoustic wave device 1A according to the first preferred embodiment will be described.

The recess 8b is formed in one surface of the support substrate 8 in the Z direction (step S10). The recess 8b is formed by dry etching after resist patterning in a portion of the one surface of the support substrate 8 in the Z direction. When resist patterning is performed, a resist on the support substrate 8 is removed after dry etching.

Forming the recess 8b is followed by filling the recess 8b with a filler (step S20). The support substrate 8 with the filler therein is planarized by grinding the surface thereof in which the filler is placed. A metal that forms an alloy with a component of the support substrate 8, such as gold or tin, can be used as the filler. A laminate of a polyimide resin layer and a copper layer may be used as the filler.

Next, the support substrate 8 with the filler therein and the piezoelectric layer 2 are stacked and combined together (step S30). The support substrate 8 and the piezoelectric layer 2 are combined by thermally joining the support substrate 8, with silicon oxide deposited on the surface thereof having the filler therein, and the piezoelectric layer 2, with silicon oxide deposited on the second principal surface 2b. In this case, layers of the silicon oxide used as joining layers are formed into the dielectric film 7. After the joining, the piezoelectric layer 2 is ground by any method to a desired thickness to form the first principal surface 2a.

Next, the interdigital transducer electrode 30 and the wires 12 are formed on the first principal surface 2a of the piezoelectric layer 2 (step S40). The interdigital transducer electrode 30 and the wires 12 are formed by forming a metal film, for example, through sputtering or evaporation, but may be formed by any method.

Then, the filler is shrunk by heat treatment to form the hollow 9 (step S50). In the heat treatment step, the filler is subjected to heat treatment at a temperature higher than that in the combining step (step S30). This melts the metal included in the filler, shrinks the filler, and generates the filling 10. For example, when the filler is a metal, such as gold, that forms a compound with the material of the support substrate 8, melting the metal generates a compound of the metal with silicon, which is a component of the support substrate 8, and forms the filling 10, which is a compound of the silicon with the metal. When the filler is a laminate of copper and polyimide resin, melting the copper generates a mixture of the copper and the polyimide resin and forms the filling 10 made of polyimide including copper. Thus, when a metal included in the filler melts, the melted metal spreads in the support substrate 8 and the volume of the filler in the recess 8b decreases. This makes the generated filling 10 smaller in volume than the recess 8b, creates a gap between the dielectric film 7 and the filling 10, and forms the hollow 9.

The acoustic wave device 1A according to the first preferred embodiment can be manufactured by the steps described above. The method for manufacturing the acoustic wave device 1A described above is merely an example and can be changed as appropriate. For example, ultraviolet irradiation may precede the heat treatment step to weaken adhesion between the dielectric film 7 and the filler.

As described above, the method for manufacturing the acoustic wave device 1A according to the first preferred embodiment includes the recess forming step of forming the recess 8b in the support substrate 8, the filling step of filling the recess 8b formed in the recess forming step with a filler, the combining step of placing the piezoelectric layer 2 onto the support substrate 8 after the filling step and combining the piezoelectric layer 2 and the support substrate 8 together, and the heat treatment step of applying heat treatment to the filler at a temperature higher than a processing temperature in the combining step to shrink the filler and form the hollow 9 in the recess 8b.

This makes it possible to form the hollow 9 in the recess 8b in the support substrate 8 without forming a through hole in the piezoelectric layer 2, and thus can reduce damage to the piezoelectric layer 2.

In a preferred embodiment, in the filling step, the filler with which to fill the recess 8b is a laminate including a polyimide resin layer and a copper layer. This allows the filler to shrink in the heat treatment step and makes it possible to form the hollow 9 in the recess 8b.

In a preferred embodiment, in the filling step, a metal forming a compound with a material of the support substrate 8 in the heat treatment step is filled as the filler in the recess 8b. This allows the filler to shrink in the heat treatment step and makes it possible to form the hollow 9 in the recess 8b.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate having a thickness in a first direction;
a piezoelectric layer extending in the first direction of the support substrate; and
an interdigital transducer electrode extending in the first direction of the piezoelectric layer and including a plurality of first electrode fingers and a plurality of second electrode fingers, the plurality of first electrode fingers extending in a second direction orthogonal to the first direction, the plurality of second electrode fingers extending in the second direction and facing corresponding ones of the plurality of first electrode fingers in a third direction orthogonal to the first direction and the second direction; wherein
the support substrate has a recess on a side thereof adjacent to the piezoelectric layer and at a position at least partially overlapping the interdigital transducer electrode in plan view in the first direction; and
a filling made of a material different from a material of the support substrate is included in a portion of the recess.

2. The acoustic wave device according to claim 1, wherein the piezoelectric layer does not have a through hole penetrating the piezoelectric layer at a position overlapping the recess in plan view in the first direction.

3. The acoustic wave device according to claim 1, wherein a material of the filling is a polyimide including copper.

4. The acoustic wave device according to claim 1, wherein a material of the filling is a compound of silicon and metal.

5. The acoustic wave device according to claim 1, further comprising:
an intermediate layer between the support substrate and the piezoelectric layer and overlapping the recess in plan view in the first direction.

6. The acoustic wave device according to claim 5, wherein a thickness of the intermediate layer is smaller than a thickness of the piezoelectric layer.

7. The acoustic wave device according to claim 1, wherein when the recess includes a hollow outside the filling, a maximum thickness of the filling is greater than a thickness of the hollow.

8. The acoustic wave device according to claim 1, wherein a thickness of the piezoelectric layer is less than or equal to about 2p, where p is a center-to-center distance between adjacent first and second electrode fingers of the plurality of first and second electrode fingers.

9. The acoustic wave device according to claim 1, wherein the piezoelectric layer includes lithium niobate or lithium tantalate.

10. The acoustic wave device according to claim 1, wherein Euler angles (φ, θ, ψ) of lithium niobate or lithium tantalate of the piezoelectric layer are in a range defined by numerical expression (1), numerical expression (2) or numerical expression (3):
(0°±10°, 0° to 20°, any ψ) numerical expression (1);
(0°±10°, 20° to 80°, 0° to 60° (1−(θ−50)²/900)^{1/2}) or (0°±10°, 20° to 80°, [180°−60° (1−(θ−50)²/900)^{1/2}] to 180°) numerical expression (2); and
(0°±10°, [180°−30° (1−(ψ−90)²/8100)^{1/2}] to 180°, any ψ) numerical expression (3).

11. The acoustic wave device according to claim 9, wherein the acoustic wave device is structured to generate thickness shear mode bulk waves.

12. The acoustic wave device according to claim 1, wherein d/p≤about 0.5 is satisfied, where d is a thickness of the piezoelectric layer and p is a center-to-center distance between adjacent first and second electrode fingers.

13. The acoustic wave device according to claim 12, wherein d/p is less than or equal to about 0.24.

14. The acoustic wave device according to claim 12, wherein when a region where adjacent first and second electrode fingers overlap in a direction in which the adjacent first and second electrode fingers face each other, as viewed in the third direction, is an excitation region, MR≤about 1.75 (d/p)+0.075 is satisfied, where MR is a metallization ratio of the plurality of first and second electrode fingers to the excitation region.

15. The acoustic wave device according to claim 1, wherein the acoustic wave device is structured to generate plate waves.

16. A method for manufacturing an acoustic wave device, the method comprising:
forming a recess in a support substrate;
filling the recess with a filler;
placing a piezoelectric layer onto the support substrate after the filling and combining the piezoelectric layer and the support substrate together; and
applying heat treatment to the filler at a temperature higher than a processing temperature in the combining to shrink the filler and form a hollow in the recess.

17. The method according to claim 16, wherein in the filling, the filler with which to fill the recess is a laminate including a polyimide resin layer and a copper layer.

18. The method according to claim 16, wherein in the filling, the filler with which to fill the recess is a metal forming a compound with a material of the support substrate in the heat treatment step.

19. The method according to claim 16, wherein a material of the filling is a polyimide including copper.

20. The method according to claim 16, wherein a material of the filling is a compound of silicon and metal.
